(19) United States
(12) Patent Application Publication
(10) Pub. No.: US 2019/0378952 A1
(43) Pub. Date: Dec. 12, 2019

(54) ENABLING LOW-COST III-V/SI INTEGRATION THROUGH NUCLEATION OF GAP ON V-GROOVED SI SUBSTRATES

(71) Applicants: Alliance for Sustainable Energy, LLC, Golden, CO (US); Colorado School of Mines, Golden, CO (US)

(72) Inventors: Emily Lowell Warren, Golden, CO (US); William Edwin McMahon, Denver, CO (US); Adele Clare Tamboli, Golden, CO (US); Emily Anne Makoutz, Redmond, WA (US); Jeramy David Zimmerman, Golden, CO (US)

(21) Appl. No.: 16/436,373

(22) Filed: Jun. 10, 2019

Related U.S. Application Data
(60) Provisional application No. 62/682,535, filed on Jun. 8, 2018.

(51) Int. Cl. H01L 31/18; H01L 21/02

(52) U.S. Cl. CPC H01L 31/1852; H01L 21/02543; H01L 21/02488; H01L 21/02433; H01L 21/0243; H01L 21/02381

(57) ABSTRACT

Disclosed herein are materials and methods useful for growth of III-V materials on Si that result in the reduction of costs for manufacturing III-V PV.

### CROSS-REFERENCE TO RELATED APPLICATION

This application claims priority under 35 U.S.C. 119(e) to U.S. Provisional Application No. 62/682,535 filed 8 Jun. 2018, the contents of which are incorporated herein by reference.

### CONTRACTUAL ORIGIN

The United States Government has rights in this invention under Contract No. DE-AC36-08GO28308 between the United States Department of Energy and Alliance for Sustainable Energy, LLC, the Manager and Operator of the National Renewable Energy Laboratory.

### BACKGROUND

Growth of III-V materials on Si could enable dramatic cost reduction for III-V PV by eliminating the need for expensive III-V substrates and enabling high-efficiency tandem solar cells. The direct heteroepitaxy of III-V materials on Si for high-efficiency photovoltaics has progressed in recent years, but most studies have focused on off-cut wafers polished using an expensive chemical-mechanical planarization process (which is not used for commercial solar cells). Alternative growth approaches are needed that can enable the integration of high material quality III-Vs with PV-grade Si materials.

III-V photovoltaics have demonstrated the highest device efficiencies, but one of the factors limiting widespread deployment is the availability of low-cost substrates. There have been decades of work on growth of III-Vs on Si, either to enable low-cost III-Vs alone or to build tandem device structures with an active Si bottom cell. However, such approaches have focused on offcut, polished wafers. GaP grown directly on Si has potential to either be a nucleation layer for a graded buffer layer to a lattice-mismatched material such as GaAsP or can serve as a direct heteroemitter for crystalline Si solar cells. To produce high quality solar cells from III-V/Si heteroepitaxy, there are several challenges such as lattice mismatch, thermal expansion mismatch, and the formation of antiphase boundaries (APBs) due to the growth of polar materials on a non-polar substrate. Recent advances in GaP/Si heteroepitaxy have shown that careful control of Si (001) surfaces (with either deliberate or nominal offcuts) prior to GaP nucleation can enable APB-free GaP films by preferentially forming double atomic steps. GaP nucleation on Si (111) has also been investigated, and the polarity of the III-V material can be controlled by varying pre-nucleation conditions.

Current approaches for 1-sun III-V/Si cell designs utilize precisely polished surfaces that can add significant cost to the manufacturing process. Demonstrated epitaxial or wafer-bonded tandems required polished Si interfaces (<0.5 nm RMS roughness for bonding, and 2-6 offcut for growth), while mechanically stacked approaches require reuse of the growth substrate to be cost effective. Adding chemomechanical polishing (CMP) can contribute at least $1/Wp,DC to the cost of the cell, which is too expensive for flat panel PV applications. For photovoltaic applications it is compelling to investigate ways to integrate III-Vs with unpolished solar-grade wafers (eliminating the need for CMP).

### SUMMARY

In an aspect disclosed herein is a method for patterning and etching an unpolished silicon substrate that is capable of III-V epitaxial growth. In an embodiment, the method further comprises treating the silicon substrate with AsH3. In another embodiment he method further comprises patterning v-grooves on the silicon substrate. In yet another embodiment, the method, the silicon substrate is oriented in the (001) direction and the v-grooves are patterned in the {110} direction before etching. In an embodiment, the v-grooves on the silicon substrate comprise (001) facets. In an embodiment, v-grooves on the silicon substrate comprise (001) facets and have not been etched to pyramids. In yet another embodiment, the layer of an oxide or SiNX is on the (001) facets of the v-grooves.

In an aspect, disclosed herein is a method for epitaxial growth of a III-V material on an unpolished silicon substrate comprising patterning v-grooves on the silicon substrate; and treating the silicon substrate with AsH₃; and epitaxially growing a III-V material on {001} and {111} surfaces of the silicon substrate. In an embodiment, the III-V material comprises a molar ratio of a group V element to a group III element of from 10 to 5000. In an embodiment, the epitaxial growth of the III-V material is at between about 600° C. and about 800° C. In an embodiment, the III-V epitaxial growth comprises nucleation of the III-V material with registry between pairs of intersecting {111} surfaces of the silicon substrate. In another embodiment, the the morphology of the nucleation of the epitaxially grown III-V material is controlled by varying growth temperatures and V/III ratios.

In an aspect, disclosed is a method for making solar cells comprising epitaxial growth of a III-V material on an unpolished silicon substrate comprising patterning v-grooves and etching. In an embodiment, the silicon substrate is oriented in the (001) direction and the v-grooves are patterned in the {110} direction. In an embodiment, the v-grooves on the silicon substrate have (001) facets. In an embodiment, the v-grooves on the silicon substrate have (001) facets and have not been etched to pyramids. In an embodiment, the silicon substrate is treated with AsH₃. In an embodiment, a layer of an oxide or SiNX is on the (001) facet of the v-grooves. In an embodiment, the III-V material comprises a molar ratio of a group V element to a group III element of from 10 to 5000. In another embodiment, the epitaxial growth of the III-V material is at between about 600° C. and about 800° C. In an embodiment, the solar cells lack antiphase boundary defects.

In an aspect, a method is disclosed for patterning and etching to create templates for selective area epitaxy on PV-grade Si substrates comprising the nucleation of III-V materials on the PV-grade Si substrates. In an embodiment, the method further involves exposing crystalline facets for epitaxy by patterning and selective wet chemical etching. In another embodiment, a solar cell is made by using the method.

In another aspect, a method of making substrates for III-V heteroepitaxy that uses planarization and patterning v-grooves on cut silicon solar-grade wafers is disclosed. In an embodiment, the method further uses AsH₃ pretreatments to remove contaminants and improve the surface structure for III-V epitaxy on {001} and {111} Si surfaces. In another embodiment, a solar cell is made by using the method.

### BRIEF DESCRIPTION OF THE DRAWINGS

Exemplary embodiments are illustrated in referenced figures of the drawings. It is intended that the embodiments and figures disclosed herein are to be considered illustrative rather than limiting.

FIGS. 1a, 1b, and 1c depict an optical image of PV-grade Czochralski Si. FIG. 1a depicts an optical image of PV-grade Czochralski Si after diamond sawing. FIG. 1b depicts an optical image of PV-grade Czochralski Si after a combined reactive-ion etching (RIE) and KOH saw-damage removal (SDR) etch. FIG. 1c depicts an optical image of PV-grade Czochralski Si [[(c)]] after a HF:HNO₃:CH₃COOH (HNA) SDR etch.

FIGS. 2a and 2b depict plan-view SEM images of Si (001) made using methods disclosed herein. FIG. 2a depicts a plan-view SEM image of lines patterned on Si (001) by nanoimprint lithography (NIL) of a sol-gel SiOₓ. FIG. 2b depicts a cross section SEM image of v-grooves patterned in Si (001) using SiOₓ/SiNₓ as a mask for tetramethylammonium hydroxide (TMAH) etching.

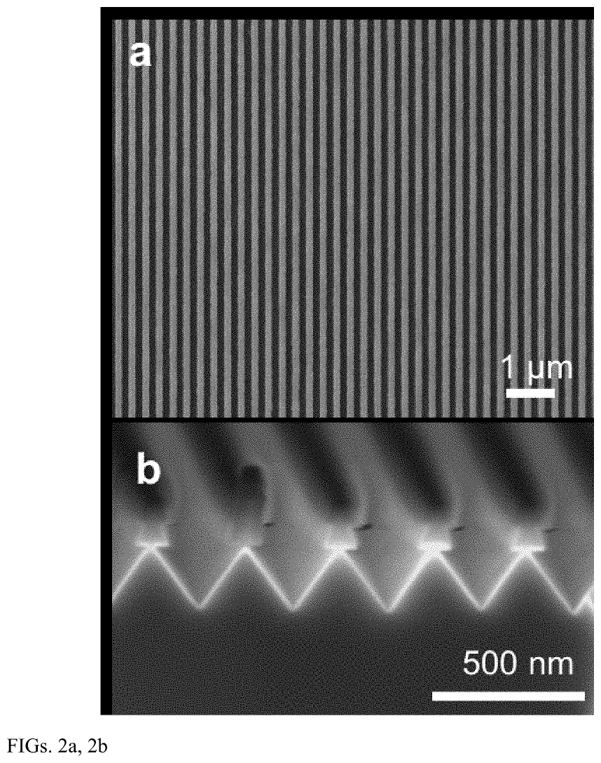

FIG. 3 depicts a schematic of a partially v-groove Si (001) and corresponding LEED images (taken at 50 eV). Colored dots are used to guide the eye for which spots are attributed to the (001), and two different {111} facets of exposed Si.

FIGS. 4a and 4b depict embodiments of defect-free epitaxy of GaP on v-grooved surfaces. FIG. 4a depicts a SEM image of GaP on SiGaP on v-groove Si. FIG. 4b depicts a series of high resolution TEM images of GaP on SiGaP on v-groove Si.

FIG. 5 depicts SEM images of GaP nucleation on v-grooved Si under varying growth conditions. In an embodiment, the V/III ratios ranged from 10 to 5000 and the GaP nucleation and growth was carried out between 600° C. and 800° C.

### DETAILED DESCRIPTION

Disclosed herein is the use of cost-effective patterning and etching approaches to create templates for selective area epitaxy on PV-grade Si substrates and the nucleation of III-V materials on these substrates.

Direct epitaxy of III-Vs on non-CMP polished surfaces is an important area of research for the integration of III-V materials with Si for photovoltaic applications. In certain embodiments disclosed herein, patterning and selective wet chemical etching were used to expose the desired crystalline facets for epitaxy, demonstrating that these surfaces are suitable for high quality heteroepitaxy of GaP.

Commercial Si solar cells are fabricated from nominally (001) oriented wafers that are textured using base etching to selectively expose Si {111} facets to create a random pyramid structures that enhance light trapping. Combining nanoscale patterning with the same facet selective etch chemistries can provide a pathway to control the facets that are exposed for epitaxy, without the need for CMP. If Si (001) substrates are patterned with lines in the {110} direction before etching, a v-grooved pattern is formed, rather than random pyramids. Epitaxy on v-grooved substrates can enable high quality nucleation of III-Vs by forcing registry between pairs of intersecting {111} surfaces to prevent defect formation. There have been several reports of using v-grooved surfaces for the metamorphic growth of high-quality lattice mismatched III-Vs such as GaAs or InP for integrating photonic or logic devices onto Si substrates, but few reports of applying controlled patterning to non-CMP Si wafers. In an embodiment, disclosed herein are approaches to low-cost planarization and patterning v-grooves on diamond-cut silicon solar-grade wafers, as well as the applicability of these substrates for III-V heteroepitaxy.

### Pattern Transfer on Non-CMP Si

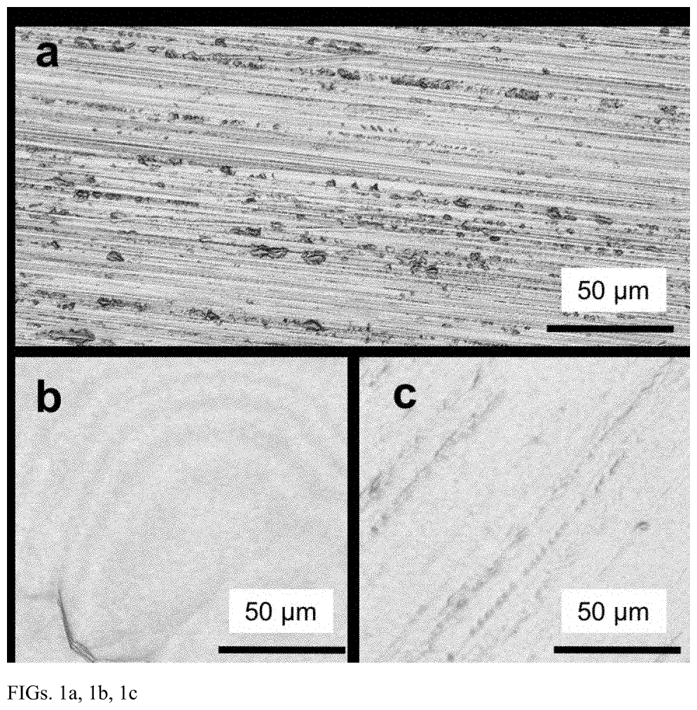

Direct patterning of as-sawn Si wafers is challenging due to the surface damage and large peak-to-valley heights left from the sawing process. Different chemical planarization techniques were investigated to minimize the peak-to-valley height difference, and surface roughness was measured across multiple sample areas using a 50× objective. As sawn PV-grade Czockralski wafers had an average RMS roughness of 716 nm (FIG. 1a). After a combined RIE and KOH etch, the RMS roughness improved to 477 nm (FIG. 1b), while an HNA etch produced a roughness of 140 nm, although saw lines were still visible by eye (FIG. 1c). By optimizing planarization etch conditions, we were able to transfer line patterns over large areas of solar-grade Si with both patterning techniques.

### AsH₃ Pretreatment of V-Grooved Si

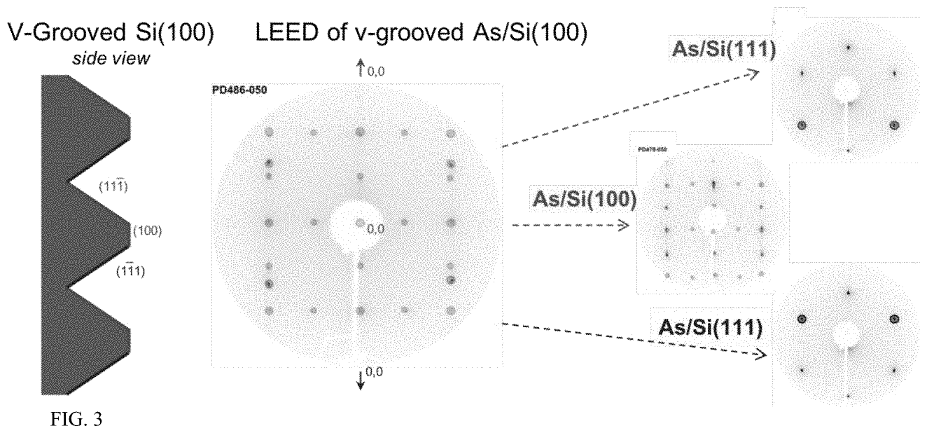

Prior work has demonstrated that AsH₃ pretreatments can remove contaminants and improve the surface structure for III-V epitaxy on both {001} and {111} Si surfaces. Before nucleating GaP, the effectiveness of the AsH₃ pre-treatment on v-grooved Si was investigated using low-energy electron diffraction (LEED) and Auger electron spectroscopy (AES). A partially etched sample on CMP polished Si {001} was annealed under standard AsH₃ conditions, and then transferred to an ultra-high vacuum (UHV) surface analysis chamber. FIG. 3 shows a schematic of the surface as well as LEED patterns for the v-grooved surface and representative planar surfaces. LEED signals from the (001) and two different {111} facets are clearly visible. AES analysis shows that the surface is free of contaminants (e.g. C, O). This indicates that the AsH₃ pretreatment can effectively be used as an in-situ surface preparation for v-grooved surfaces.

### GaP Nucleation on V-Grooved Si

When v-grooves were not fully etched to pyramids and (001) facets remained along the ridge-tops (as depicted in FIG. 3), GaP selectively nucleated on the (001) and did not fill the v-grooves. When a protective layer of oxide or SiNₓ was left on the ridges, nucleation occurred only within the channels on {111} facets. Without being bound by theory, this can be explained by the lower sticking coefficient of GaP on the {111} surfaces relative to the {001} and provides a way to control facet-selective nucleation. In an embodiment, the nucleation morphology can be controlled by varying temperature and the ratio of the group V such as PH₃ and group III such as trimethylgallium (TMGa).

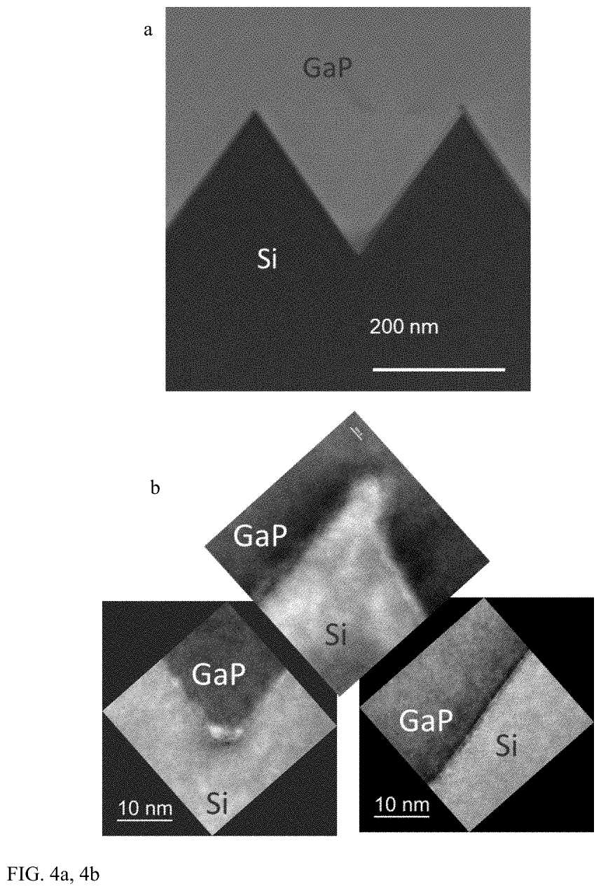

As depicted in FIG. 4, GaP growth on v-grooved surfaces is essentially defect free.

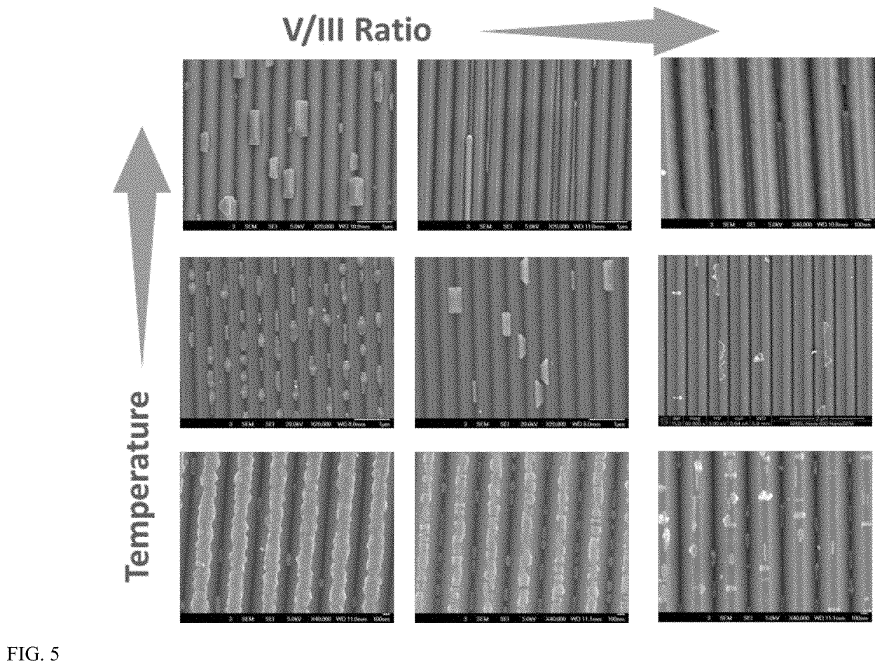

As depicted in FIG. 5, the amount of nucleation of GaP on v-grooved Si can be controlled by varying temperatures and V/III ratios.

### Materials and Methods

Patterning was investigated on Czochralski (CZ) solargrade Si wafers cut with a diamond saw as well as CMP polished CZ wafers. For solar-grade wafers, aqueous KOH and HF:HNO₃:CH₃COOH (HNA) etch chemistries, as well as reactive ion etching were investigated as planarizing etches. Patterns were transferred into SiNₓ or SiOₓ dielectric layers using nanoimprint lithography (NIL) and laser interference lithography (LIL). Reactive ion etching and dilute (1%) HF were used to selectively remove the dielectric masks, then v-grooves were formed by etching the samples in 10% TMAH.

III-V growth was carried out in a low pressure MOCVD reactor using triethylgallium and PH₃ as precursors. In an embodiment, trimethylgallium may be used. Prior to growth, samples were annealed in dilute AsH₃, which has previously been shown to remove C and O contaminants and for Si (001) substrates, to create a single domain arsenic terminated surface. For surface analysis, samples were transferred to a linked ultrahigh-vacuum (UHV) surface analysis chamber equipped with low-energy electron diffraction (LEED) and Auger electron spectroscopy (AES). The surface roughness of Si wafers was measured using a Keyence VK-X250 3D scanning laser microscope with 0.5 nm resolution in the z-direction.

GaP growth was carried out in an MOCVD reactor, using PH₃ as a group V precursor and either triethyl gallium or trimethyl gallium as a group III precursor. Wet chemical etching and an in-situ surface clean was done to prepare the surface for growth. In an embodiment, V/III ratios ranged from 10 to 5000. In an embodiment, GaP nucleation and growth was carried out between 600° C. and 800° C.

We claim:

1. A method for patterning and etching an unpolished silicon substrate that is capable of III-V epitaxial growth.

2. The method of claim 1 further comprising treating the silicon substrate with AsH₃.

3. The method of claim 1 comprising patterning v-grooves on the silicon substrate.

4. The method of claim 3 wherein the silicon substrate is oriented in the (001) direction and the v-grooves are patterned in the {110} direction before etching.

5. The method of claim 4 wherein the v-grooves on the silicon substrate comprise (001) facets.

6. The method of claim 4 wherein the v-grooves on the silicon substrate comprise (001) facets and have not been etched to pyramids.

7. The method of claim 5 wherein a layer of an oxide or SiNX is on the (001) facets of the v-grooves.

8. A method for epitaxial growth of a III-V material on an unpolished silicon substrate comprising patterning v-grooves on the silicon substrate; and
treating the silicon substrate with AsH₃; and
epitaxially growing a III-V material on {001} and {111} surfaces of the silicon substrate.

9. The method of claim 8 wherein the III-V material comprises a molar ratio of a group V element to a group III element of from 10 to 5000.

10. The method of claim 8 wherein the epitaxial growth of the III-V material is at between about 600° C. and about 800° C.

11. The method of claim 8 wherein the III-V epitaxial growth comprises nucleation of the III-V material with registry between pairs of intersecting {111} surfaces of the silicon substrate.

12. The method of claim 11 wherein the morphology of the nucleation of the epitaxially grown III-V material is controlled by varying growth temperatures and V/III ratios.

13. A method for making solar cells comprising epitaxial growth of a III-V material on an unpolished silicon substrate comprising patterning v-grooves and etching.

14. The method of claim 13 wherein the silicon substrate is oriented in the (001) direction and the v-grooves are patterned in the {110} direction.

15. The method of claim 14 wherein the v-grooves on the silicon substrate have (001) facets.

16. The method of claim 14 wherein the v-grooves on the silicon substrate have (001) facets and have not been etched to pyramids.

17. The method of claim 13 further comprising treating the silicon substrate with AsH₃.

18. The method of claim 14 wherein a layer of an oxide or SiNₓ is on the (001) facet of the v-grooves.

19. The method of claim 13 wherein the III-V material comprises a molar ratio of a group V element to a group III element of from 10 to 5000.

20. The method of claim 13 wherein the epitaxial growth of the III-V material is at between about 600° C. and about 800° C.

21. The method of claim 13 wherein the solar cells lack antiphase boundary defects.
